(19) United States
(12) Patent Application Publication
(10) Pub. No.: US 2014/0320233 A1
(43) Pub. Date: Oct. 30, 2014

(54) NETWORK SIGNAL TRANSMISSION MATCH STRUCTURE USED IN ELECTRICAL CONNECTOR

(71) Applicant: KINNEXA, INC., Taipei City (TW)

(72) Inventor: KUAN-HSIUNG WEI, Taipei City (TW)

(21) Appl. No.: 13/945,929

(22) Filed: Jul. 19, 2013

(30) Foreign Application Priority Data
Apr. 26, 2013 (TW) 102207730

(51) Int. Cl. H03H 7/38; H01R 13/719

(52) U.S. Cl. CPC H03H 7/38; H01R 13/719
USPC 333/32

(57) ABSTRACT

A transmission match structure is arranged in an RJ connector and includes two substrates, a plurality of signal transmission sets and a plurality of signal transformers mounted to the substrates, and two coupling devices arranged between the substrates. The signal transmission sets are formed by respectively connecting in series a plurality of capacitors and inductors. The signal transformers includes a plurality of magnetic coils connected respectively in series with each of the capacitors and each of the inductors to form electrical connection. Each of the coupling devices is electrically connected, via each of the substrates, to each of the signal transmission sets and each of the signal transformers. As such, practical improvements of having excellent IEEE and EMI properties, being free of impedance matching problem, and providing efficient and stable manufacturability can be achieved.

### (a) TECHNICAL FIELD OF THE INVENTION

The present invention generally relates to a transmission match structure, and more particularly to a network signal transmission match structure that is provided for use in an electrical connect and shows excellent IEEE and EMI properties, has no impedance matching problems, can be efficiently manufactured, and is stable.

### (b) DESCRIPTION OF THE PRIOR ART

A conventional network connector adopts an arrangement of connecting a plurality of signal transformers in cascade to provide the desired conditions of operation. However, the signal transformers each show individual electrical characteristics in shipment or manufacture (due to being affected by various factors, including density of wire wrapping, varying thickness of wires, or more detailedly the content of copper in the wires), so that the manually-conducted fine adjustment is necessary for the manufacture of the network connector and this leads to loss of manufacturing time and may further cause issues of matching and electromagnetic interference (due to wire stretching being varying in the manufacture that affect the EMI characteristics thereof). An apparent influence may thus be imposed on the speed and quality of transmission of information in networks.

### SUMMARY OF THE INVENTION

The primary object of the present invention is to enhance various electrical characteristics of the network connector, to increase the manufacturing speed, and to improve the quality.

The present invention is arranged in an RJ connector and comprises at least two the substrates. Each of the substrates is provided with a plurality of signal transmission sets mounted thereto through surface mounting technology. Each of the signal transmission sets is formed by connecting in series a plurality of capacitors and a plurality of inductors. Each of the substrates is provided with a plurality of signal transformers mounted thereto. Each of the signal transformers comprises a plurality of magnetic coils, each of which is connected in series with each of the capacitors and each of the inductors to electrical connection. The substrates are provided therebetween with at least two coupling devices, each of which is electrically connected, via each of the substrates, to each of the signal transmission sets and each of the signal transformers.

As such, by applying surface mounting technology to mount capacitors and inductors to substrates to form signal transmission sets and to connect, in series, with each of the magnetic coils of each of the signal transformers, manufacturing speed and quality can be improved. Further, in operation, through the collaboration of the capacitors and the inductors, various electrical characteristics can be significantly improved, so as to allow the present invention to achieve practical advantages of having excellent IEEE and EMI properties, being free of impedance matching problems, and providing efficient and stable manufacturability.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a perspective view showing a preferred embodiment of the present invention.

FIG. 2 is an exploded view of the preferred embodiment of the present invention.

FIG. 3 is a schematic view showing the preferred embodiment of the present invention in a partially assembled condition.

FIG. 4 is a perspective view showing a coupling device of the preferred embodiment of the present invention.

FIG. 5 is a block diagram showing the structure of a substrate of the preferred embodiment of the present invention.

FIG. 6 is a schematic view showing an application of another preferred embodiment of the present invention.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

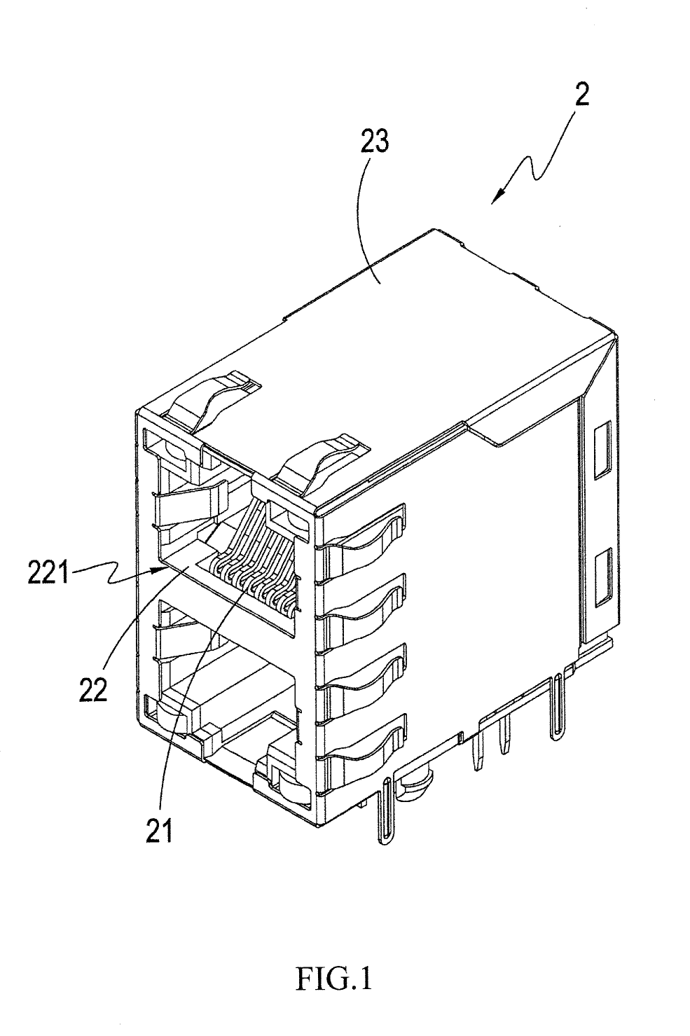

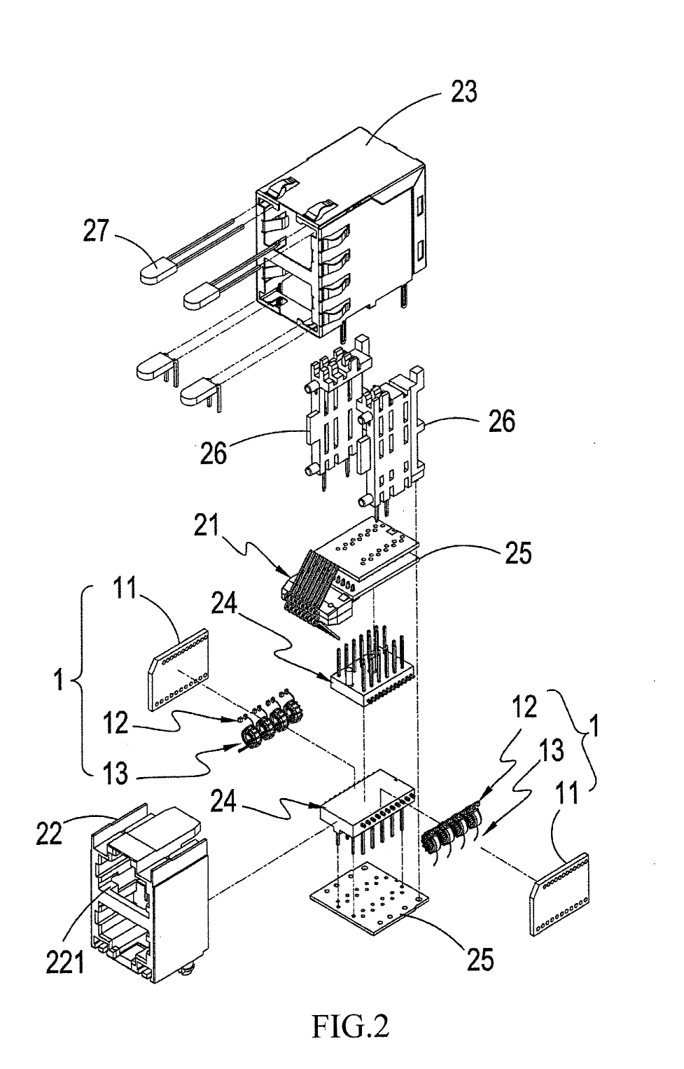

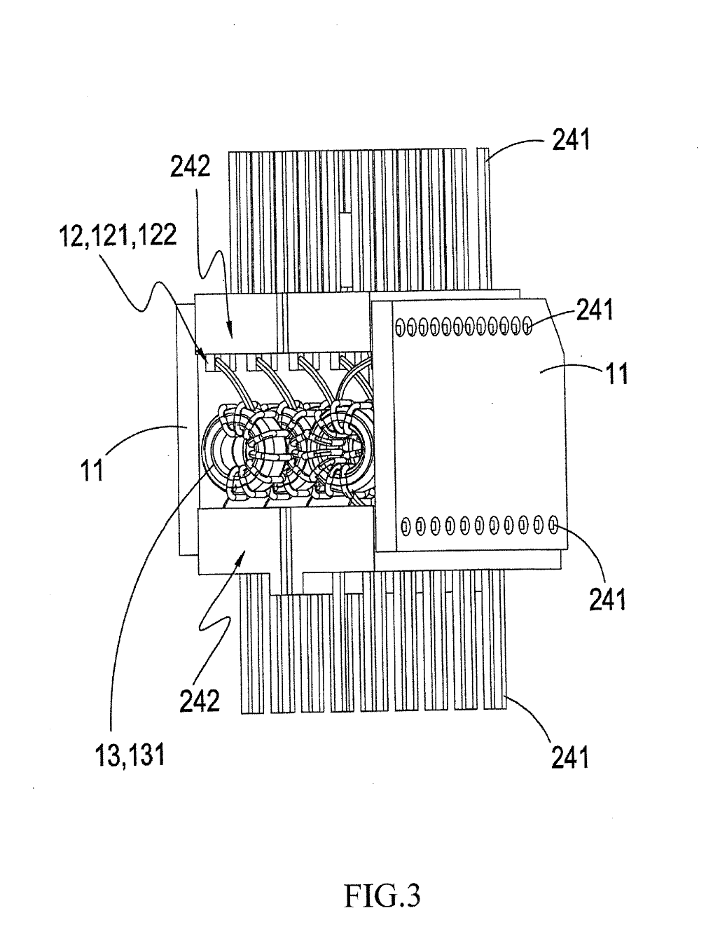

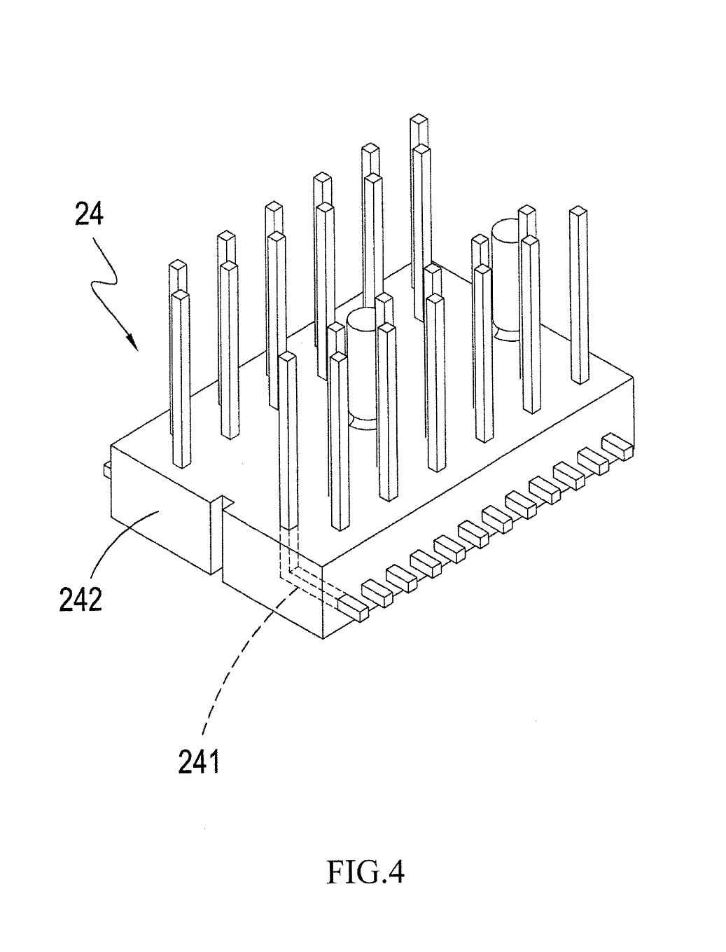

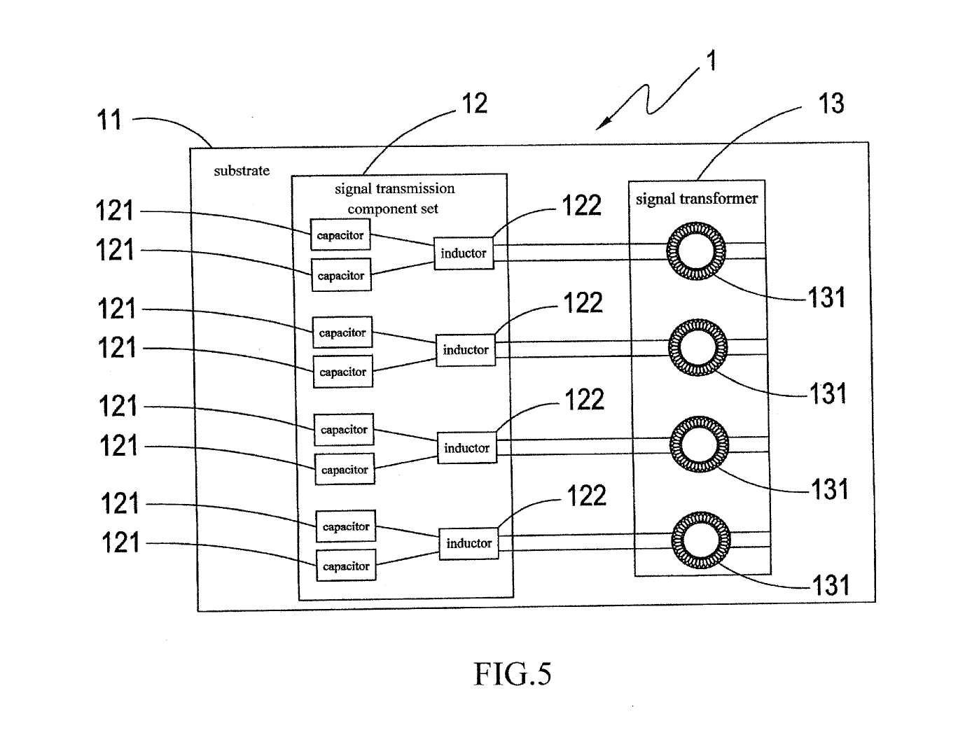

Referring to FIGS. 1-5, which are respectively a perspective view and an exploded view of a preferred embodiment of the present invention, a schematic view showing the preferred embodiment in a partially assembled condition, a perspective view showing a coupling device of the present invention, and a block diagram showing the structure of a substrate of the present invention, these drawings clearly show that the present invention provides a transmission match structure 1 that is arranged in an RJ connector 2 and comprises at least two substrates 11, a plurality of signal transmission sets 12, a plurality of signal transformers 13, and at least two coupling devices 24. The substrates 11 are preferably printed circuit boards (PCBs). Each of the substrates 11 is provided, at least at one side thereof, with at least one isolation board 26. Each of the signal transmission sets 12 comprises a plurality of capacitors 121 and a plurality of inductors 122 connected in series. Each of the signal transmission sets 12 is mounted, through surface-mounting technology (SMT), to each of the substrates 11. Each of the signal transformers 13 is provided on the substrates 11. Each of the signal transformers 13 comprises a plurality of magnetic coils 131. Each of the magnetic coils 131 is connected in series with each of the capacitors 121 and each of the inductors 122 to form electrical connection. Each of the signal transformers 13 makes use of each of each of the capacitors 121 and each of the inductors 122 of each of the signal transmission sets 12 to provide IEEE characteristics and to provide an achievement of no impedance matching problem. Each of the coupling devices 24 is arranged and mounted between the substrates 11. The coupling devices 24 are provided in an arrangement of upper and lower levels. Each of the coupling devices 24 is electrically connected via each of the substrates 11 to each of the signal transmission sets 12 and each of the signal transformers 13. Each of the coupling devices 24 comprises a plurality of connection pins 241 and at least one carrier 242 that carries and holds each of the connection pins 241. Each of the connection pins 241 is electrically connected to each of the signal transmission sets 12 and each of the signal transformers 13. Each of the connection pins 241 shows a configuration of an L-shape. Each of the coupling devices 24 is electrically connected to at least one circuit board 25. The circuit board 25 is electrically connected to at least one light-emitting module 27 and the circuit board 25 is electrically connected to at least one golden finger module 21 and the golden finger module 21 is partially received in at least one insulation body 22. The insulation body 22 forms at least one insertion opening 221 that partially exposes the golden finger module 21. The RJ connector 2 further comprises an external shielding member 23 that houses each of the substrates 11, each of the coupling devices 24, the circuit boards 25, the golden finger modules 21, and the insulation body 22. The external shielding member 23 does not shield and cover the insertion opening 221. The above-described arrangement illustrates one of the various embodiments of the present invention, and the present invention is not limited to such an arrangement.

To manufacture, each of the signal transmission sets 12 and each of the signal transformers 131 that are necessary according to a desired manufacturing specification are respectively mounted to each of the substrates 11. Since each of the signal transmission sets 12 is mounted to each of the substrates 11 through surface mounting technology (SMT), the manufacturing process can be carried out very quickly. Further, each of the magnetic coils 131 is connected in series with each of the capacitors 121 and each of the inductors 122, so that enhancement of product quality and being free of impedance matching problem can be achieved. Further, since each of the capacitors 121 and each of the inductors 122 are generally specification-complied standard products, the electrical property is generally stable so that the desired characteristics required according to IEEE can be achieved and excellent EMI property is provided.

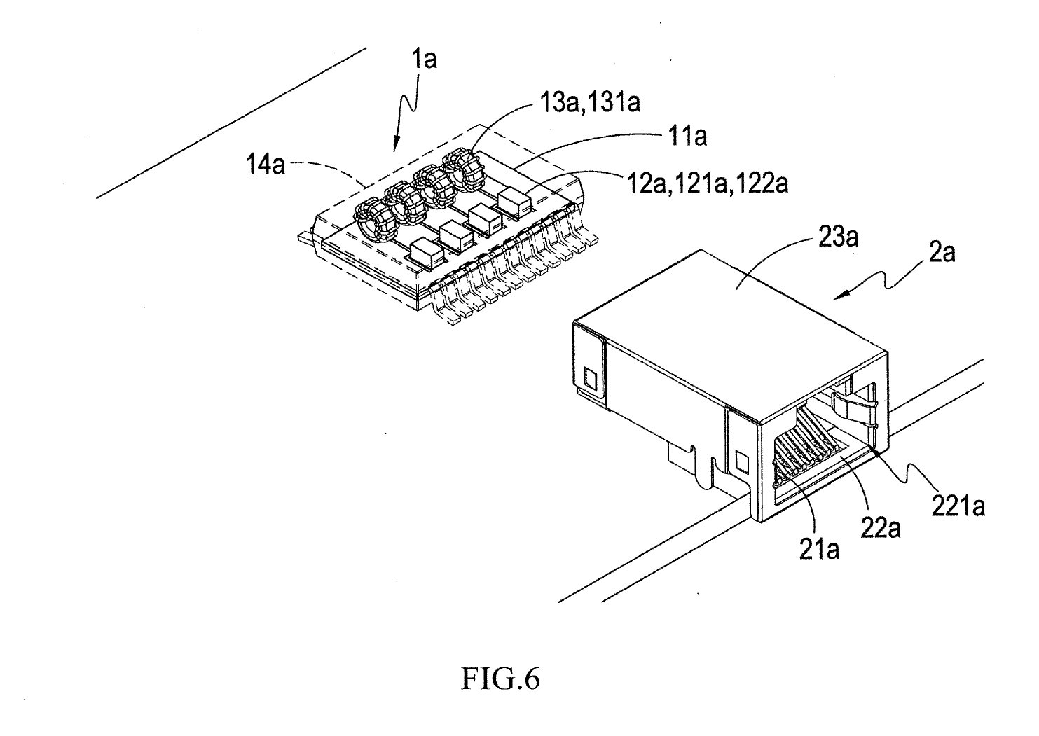

As shown in FIG. 6, which is a schematic view showing an application of another embodiment of the present invention, the drawing clearly shows that the present invention is provided for forming information communication with an RJ connector 2a. The transmission match structure 1a comprises at least one substrate 11a, at least one signal transmission set 12a, and at least one signal transformer 13a. The signal transmission set 12a is formed by a plurality of capacitors 121a respectively connected in series with a plurality of inductors 122a. The signal transmission sets 12a is mounted, via surface mounting technology (SMT), to the substrate 11a. The signal transformer 13a is mounted on the substrate 11a. The signal transformer 13a comprises a plurality of magnetic coils 131a. Each of the magnetic coils 131a is connected in series with each of the capacitors 121a and each of the inductors 122a to form electrical connection. Further, the signal transformer 13a makes use of each of the capacitors 121a and each of the inductors 122a of the signal transmission set 12a to provide IEEE characteristics and to provide an achievement of no impedance matching problem. However, the instant embodiment is different from the previous embodiment in that the transmission match structure 1a is set in information communication with the RJ connector 2a and the RJ connector 2a comprises at least one golden finger module 21a, at least one insulation body 22a that receives the golden finger module 21a therein, and at least one external shielding member 23a that houses the insulation body 22a. The golden finger module 21a is in information communication with the transmission match structure 1a. The insulation body 22a forms at least one insertion opening 221a to partially expose the golden finger module 21a. The external shielding member 23a does not shield and cover the insertion opening 221a. Further, the signal transmission set 12a and the signal transformer 13a are housed in at least one packaging element 14a.

Thus, the technical features that the present invention adopts to improve the prior art are as follows:

(1) By mean of the collaborative combination of each of the substrates 11, each of the capacitors 121 and each of the inductors 122 of each of the signal transmission sets 12, and each of the signal transformers 13, the present invention achieves practical improvements of having excellent IEEE and EMI properties and being free of impedance matching problem.

(2) By mean of the collaborative combination of each of the substrates 11, each of the capacitors 121 and each of the inductors 122 of each of the signal transmission sets 12, and each of the signal transformers 13, the present invention achieves a practical improvement of efficient and stable manufacturability.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A network signal transmission match structure for use in an electrical connector, the transmission match structure being arranged in an RJ connector and comprising:
at least two the substrates;
a plurality of signal transmission sets, each of which comprises a plurality of capacitors and a plurality of inductors connected in series and is mounted, via surface mounting technology, to each of the substrates;
a plurality of signal transformers, each of which is mounted on each of the substrates, each of the signal transformers comprising a plurality of magnetic coils, each of the magnetic coils being connected, in series, with each of the capacitors and each of the inductors to form electrical connection, each of the signal transformers making use of each of the capacitors and each of the inductors of each of the signal transmission sets to provide IEEE characteristics and eliminate problems of impedance matching; and
at least two the coupling devices, each of which is arranged and mounted between each of the substrates, each of the coupling devices being electrically connected, via each of the substrates, to each of the signal transmission sets and each of the signal transformers.

2. The network signal transmission match structure for use in an electrical connector according to claim 1, wherein each of the coupling devices comprises a plurality of connection pins and at least one carrier that carries and holds each of the connection pins, each of the connection pins being electrically connected to each of the signal transmission sets and each of the signal transformers, each of the connection pins showing a configuration of an L-shape.

3. The network signal transmission match structure for use in an electrical connector according to claim 1, wherein the coupling devices are arranged as upper and lower levels and each of the coupling devices is electrically connected to at least one circuit board, the circuit board being electrically connected to at least one light-emitting module.

4. The network signal transmission match structure for use in an electrical connector according to claim 3, wherein the circuit board is electrically connected to at least one golden finger module, the golden finger module being partially received in at least one insulation body, the insulation body forming at least one insertion opening that partially exposes the golden finger module.

5. The network signal transmission match structure for use in an electrical connector according to claim 4, wherein the insulation body is housed in at least one external shielding member that is constructed not to shield and cover the insertion opening, the external shielding member further housing each of the substrates, each of the coupling devices, each of the circuit boards, and the golden finger modules.

6. The network signal transmission match structure for use in an electrical connector according to claim 1, wherein each of the substrates comprises a printed circuit board, each of the substrates being provided, at least one side thereof, with at least one isolation board.

7. A network signal transmission match structure for use in an electrical connector, which is in information communication with an RJ connector, the transmission match structure comprising:
at least one substrate;
at least one signal transmission set, which comprises a plurality of capacitors and a plurality of inductors connected in series, the signal transmission set being mounted through surface mounting technology to the substrate;
at least one signal transformer, which is mounted on the substrate and comprises a plurality of magnetic coils, each of which is connected in series with each of the capacitors and each of the inductors to form electrical connection, the signal transformers making use of each of the capacitors and each of the inductors of the signal transmission set to provide IEEE characteristics and to provide an achievement of no impedance matching problem.

8. The network signal transmission match structure for use in an electrical connector according to claim 7, wherein the RJ connector comprises at least one golden finger module, at least one insulation body that receives the golden finger module, and at least one external shielding member that houses the insulation body, the golden finger module being in information communication with the transmission match structure.

9. The network signal transmission match structure for use in an electrical connector according to claim 8, wherein the insulation body forms at least one insertion opening to partially expose the golden finger module, the external shielding member being constructed not to shield and cover the insertion opening.

10. The network signal transmission match structure for use in an electrical connector according to claim 7, wherein the signal transmission set and the signal transformer are housed in at least one packaging element.
